(19) United States
(12) Patent Application Publication
(10) Pub. No.: US 2019/0035828 A1
(43) Pub. Date: Jan. 31, 2019

(54) BACKSIDE ILLUMINATED IMAGE SENSOR AND METHOD OF MANUFACTURING THE SAME

(71) Applicant: DB HITEK CO., LTD., Seoul (KR)

(72) Inventor: Chang Hun HAN, Icheon-si (KR)

(21) Appl. No.: 16/046,148

(22) Filed: Jul. 26, 2018

(30) Foreign Application Priority Data
Jul. 26, 2017 (KR) 10-2017-0094761

(51) Int. Cl. H01L 27/146; H01L 21/763; H01L 21/762

(52) U.S. Cl. CPC H01L 27/1463; H01L 27/1464; H01L 27/14623; H01L 27/14636; H01L 27/14627; H01L 21/763; H01L 21/76224; H01L 27/14689; H01L 27/14621; H01L 27/14685

(57) ABSTRACT

A backside illuminated image sensor includes pixel regions disposed in a substrate, wiring layers disposed on a frontside surface of the substrate and electrically connected with the pixel regions, a color filter layer disposed on a backside surface of the substrate, a micro lens array disposed on the color filter layer, and isolation regions configured to electrically isolate the pixel regions from each other. Each of the isolation regions includes a deep trench isolation region and a shallow trench isolation region disposed on the deep trench isolation region.

### CROSS-REFERENCE TO RELATED APPLICATION

This application claims the priority benefit of Korean Patent Application No. 10-2017-0094761, filed on Jul. 26, 2017, and all the benefits accruing therefrom under 35 U.S.C. § 119, the contents of which are incorporated by reference in their entirety.

### TECHNICAL FIELD

The present disclosure relates to a generally to the field of image sensors and in particular to the field of backside illuminated image sensors a methods of manufacturing the same.

### BACKGROUND

The present disclosure relates to a backside illuminated image sensor and a method of manufacturing the same.

In general, an image sensor is a semiconductor device that converts an optical image into electrical signals. Image sensors known in the art include charge coupled devices (CCDs) and CMOS image sensors. The CMOS image sensor includes unit pixels, each including a photodiode and MOS transistors. The CMOS image sensor sequentially detects the electrical signals of the unit pixels using a switching method, thereby forming an image. The CMOS image sensor may be classified into a frontside illuminated image sensor and a backside illuminated image sensor.

A front side illuminated (or front-illuminated) image sensor may include photodiodes formed in a substrate, transistors formed on a front surface of the substrate, wiring layers formed on the front surface of the substrate, and a color filter layer and micro lens array formed on the wiring layers.

The backside illuminated (or back-illuminated) image sensor may have an improved light-receiving efficiency in comparison with the frontside illuminated image sensor. The backside illuminated image sensor may include transistors and wiring layers formed on a frontside surface of a substrate, a light-blocking pattern and an anti-reflective layer formed on a backside surface of the substrate, a passivation layer formed on the light-blocking pattern and the anti-reflective layer, and a color filter layer and a micro lens array formed on the passivation layer.

While backside illuminated image sensors can have an improved light-receiving efficiency in comparison with front side illuminated image sensors, backside illuminated image sensors can be more difficult to manufacture, resulting in lower yields and higher prices.

One manufacturing difficulty can result during a back-grinding process which may be performed to reduce a thickness of the substrate. Bulk Micro-Defects (BMD) functioning as gettering sites in the substrate or a polysilicon layer on a backside surface of the substrate may be removed by the back-grinding process. As a result, the substrate may be contaminated with metal contaminants while forming the anti-reflective layer, the light-blocking pattern, and the like on the backside surface of the substrate, and the metal contaminants in the substrate may increase the dark current of the backside illuminated image sensor.

### SUMMARY

The present disclosure provides a backside illuminated image sensor capable of reducing the dark current caused by to metal contaminants and a method of manufacturing the backside illuminated image sensor.

In accordance with an aspect of the present disclosure, a backside illuminated image sensor may include a substrate presenting a frontside surface and a backside surface, a plurality of pixel regions disposed in the substrate, a plurality of wiring layers disposed on a frontside surface of the substrate and electrically connected with the plurality of the pixel regions, a color filter layer disposed on a backside surface of the substrate, a micro lens array disposed on the color filter layer, and a plurality of isolation regions configured to electrically isolate the plurality of pixel regions from each other. Each of the plurality of isolation regions may include a deep trench isolation region and a shallow trench isolation region disposed on the deep trench isolation region.

In accordance with some embodiments of the present disclosure, the plurality of deep trench isolation regions may include impurity doped polysilicon.

In accordance with some embodiments of the present disclosure, the plurality of shallow trench isolation regions may include silicon oxide.

In accordance with some embodiments of the present disclosure, each shallow trench isolation region may include a liner insulating layer and a silicon oxide region disposed on the liner insulating layer.

In accordance with some embodiments of the present disclosure, each deep trench isolation region may extend from the corresponding shallow trench isolation region to the backside surface of the substrate.

In accordance with some embodiments of the present disclosure, each of the plurality of pixel regions may include a charge accumulation region disposed in the substrate, and a frontside pinning layer disposed between the frontside surface of the substrate and the charge accumulation region.

In accordance with some embodiments of the present disclosure, the each of the plurality of pixel regions may further include a backside pinning layer disposed between the backside surface of the substrate and the charge accumulation region.

In accordance with some embodiments of the present disclosure, the backside illuminated image sensor may further include an anti-reflective layer disposed on the backside surface of the substrate, a light-blocking pattern disposed on the anti-reflective layer and having or defining openings, each opening corresponding to one of the pixel regions of the plurality of pixel regions, and a passivation layer disposed on the anti-reflective layer and the light-blocking pattern, wherein the color filter layer may be disposed on the passivation layer.

In accordance with another aspect of the present disclosure, a backside illuminated image sensor may include plurality of pixel regions disposed in a substrate, plurality of wiring layers disposed on a frontside surface of the substrate and electrically connected to the plurality of pixel regions, a color filter layer disposed on a backside surface of the substrate, a micro lens array disposed on the color filter layer, a plurality of isolation regions configured to electrically isolate the pixel regions from each other, and a plurality of gettering regions extending from the isolation regions toward the backside surface of the substrate to collect contaminants in the substrate.

In accordance with some embodiments of the present disclosure, the plurality of gettering regions may include impurity doped polysilicon.

In accordance with some embodiments of the present disclosure, the plurality of isolation regions may be disposed in frontside surface portions of the substrate, and the plurality of gettering regions may extend to the backside surface of the substrate.

In accordance with still another aspect of the present disclosure, a method of manufacturing a backside illuminated image sensor may include forming a plurality of isolation regions in a substrate in order to electrically isolate pixel regions from each other, forming the plurality of pixel regions in the substrate, forming a plurality of wiring layers on a frontside surface of the substrate to be electrically connected to the plurality of pixel regions, forming a color filter layer on a backside surface of the substrate, and forming a micro lens array on the color filter layer. Forming the plurality of isolation regions may include a plurality of forming deep trench isolation regions in the substrate, and forming a plurality of shallow trench isolation regions on the deep trench isolation regions.

In accordance with some embodiments of the present disclosure, the deep trench isolation regions may include impurity doped polysilicon.

In accordance with some embodiments of the present disclosure, forming the plurality of isolation regions may further include forming a plurality of shallow trenches in frontside surface portions of the substrate, and forming a plurality of deep trenches extending from the plurality of shallow trenches toward the backside surface of the substrate, wherein the plurality of deep trench isolation regions may be formed in the plurality of deep trenches, and the shallow trench isolation regions may be formed in the plurality of shallow trenches.

In accordance with some embodiments of the present disclosure, forming the plurality of isolation regions may further include forming a liner insulating layer on inner surfaces of the plurality of shallow trenches.

In accordance with some embodiments of the present disclosure, forming the plurality of deep trench isolation regions may include forming an impurity doped polysilicon layer on the frontside surface of the substrate so that the deep trenches are buried, and partially removing the impurity doped polysilicon layer in order to form the deep trench isolation regions in the deep trenches.

In accordance with some embodiments of the present disclosure, forming the plurality of deep trench isolation regions may include forming a polysilicon layer on the frontside surface of the substrate so that the plurality of deep trenches are buried, performing an ion implantation process for doping portions of the polysilicon layer formed in the deep trenches with an impurity, and partially removing the polysilicon layer in order to form the deep trench isolation regions in the deep trenches.

In accordance with some embodiments of the present disclosure, the method may further include performing a back-grinding process so that the plurality of deep trench isolation regions are exposed after forming the plurality of wiring layers.

In accordance with some embodiments of the present disclosure, forming the plurality of pixel regions may include forming a plurality of charge accumulation regions in the substrate, and forming a plurality of frontside pinning layers between the frontside surface of the substrate and the plurality of charge accumulation regions.

In accordance with some embodiments of the present disclosure, forming the plurality of pixel regions may further include forming a plurality of backside pinning layers between the backside surface of the substrate and the plurality of charge accumulation regions.

In accordance with some embodiments of the present disclosure, the method may further include forming an anti-reflective layer on the backside surface of the substrate, forming a light-blocking pattern defining openings, each opening corresponding to a pixel region of the plurality of pixel regions on the anti-reflective layer, and forming a passivation layer on the anti-reflective layer and the light-blocking pattern, wherein the color filter layer may be formed on the passivation layer.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a cross-sectional view illustrating a backside illuminated image sensor in accordance with an embodiment of the present disclosure;

FIG. 2 is a cross-sectional view illustrating another example of isolation regions as shown in FIG. 1; and

FIGS. 3 to 17 are cross-sectional views illustrating a method of manufacturing the backside illuminated image sensor as shown in FIG. 1.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

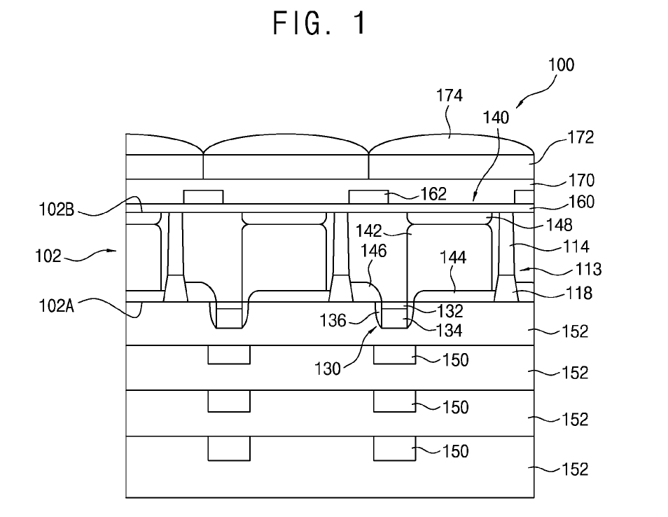

FIG. 1 is a cross-sectional view illustrating a backside illuminated image sensor in accordance with an embodiment of the present disclosure.

Referring to FIG. 1, a backside illuminated image sensor 100, in accordance with an embodiment of the present disclosure, may include pixel regions 140 disposed in a substrate 102. Each of the pixel regions 140 may include a charge accumulation region 142 in which charges generated by the incident light are accumulated. The charge accumulation regions 142 may be disposed in the substrate 102, and floating diffusion regions 146 may be disposed in frontside surface portions of the substrate 102 to be spaced apart from the charge accumulation regions 142.

The substrate 102 may have a first conductivity type, and the charge accumulation regions 142 and the floating diffusion regions 146 may have a second conductivity type. For example, a p-type substrate may be used as the substrate 102, and n-type impurity diffusion regions functioning as the charge accumulation regions 142 and the floating diffusion regions 146 may be formed in the p-type substrate 102.

Transfer gate structures 130 may be disposed on channel regions between the charge accumulation regions 142 and the floating diffusion regions 146 to transfer the charges accumulated in the charge accumulation regions 142 to the floating diffusion regions 146. Each of the transfer gate structures 130 may include a gate insulating layer 132 disposed on a frontside surface 102A of the substrate 102, a gate electrode 134 disposed on the gate insulating layer 132, and gate spacers 136 disposed on side surfaces of the gate electrode 134. Further, though not shown in figures, the backside illuminated image sensor 100 may include reset transistors, source follower transistors, and select transistors electrically connected with the floating diffusion regions 146.

Alternatively, if the backside illuminated image sensor 100 is a 3T (or fewer than three transistors) layout, the transfer gate structures 130 may be used as reset gate structures and the floating diffusion regions 146 may be used as active regions for connecting the charge accumulation regions 142 with reset circuitries.

The pixel regions 140 may include a frontside pinning layer 144 disposed between the frontside surface 102A of the substrate 102 and the charge accumulation regions 142, respectively. Further, the pixel regions 140 may include a backside pinning layer 148 disposed between a backside surface 102B of the substrate 102 and the charge accumulation regions 142, respectively. The frontside and backside pinning layers 144 and 148 may have the first conductivity type. For example, p-type impurity diffusion regions may be used as the frontside and backside pinning layers 144 and 148.

Wiring layers 150 may be disposed on the frontside surface 102A of the substrate 102 and may be electrically connected with the pixel regions 140. Further, insulating layers 152 may be disposed on the frontside surface 102A of the substrate 102 and between the wiring layers 150.

An anti-reflective layer 160 may be disposed on the backside surface 102B of the substrate 102, and a light-blocking pattern 162 having openings 164 (as depicted in FIG. 17) corresponding to the pixel regions 140 may be disposed on the anti-reflective layer 160. Further, a passivation layer 170 may be disposed on the anti-reflective layer 160 and the light-blocking pattern 162, a color filter layer 172 may be disposed on the passivation layer 170, and a micro lens array 174 may be disposed on the color filter layer 172.

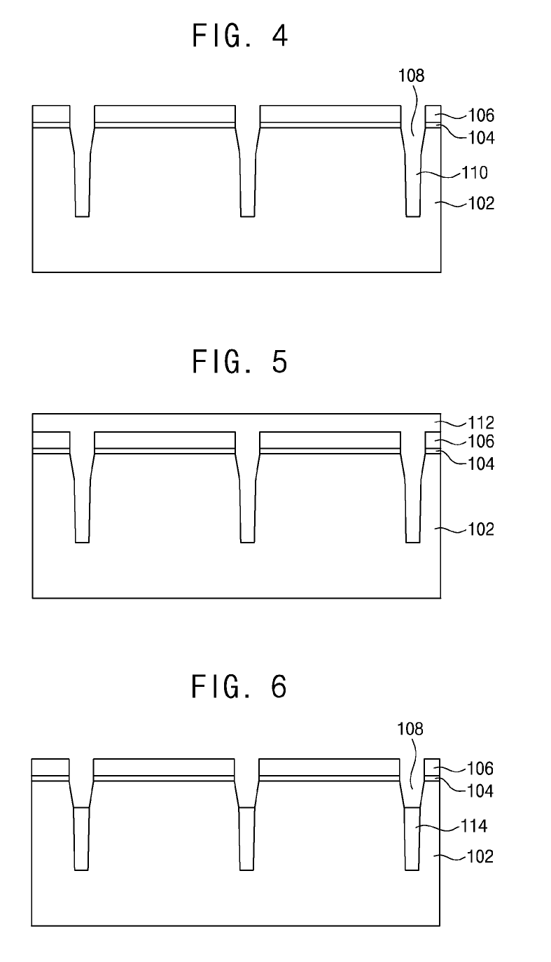

In accordance with an embodiment of the present disclosure, the pixel regions 140 may be electrically isolated by isolation regions 113 from each other. Each of the isolation regions 113 may include a deep trench isolation region 114 and a shallow trench isolation region 118 disposed on the deep trench isolation region 114. For example, shallow trenches 108 (as depicted in FIG. 3) may be formed in frontside surface portions of the substrate 102, and deep trenches 110 (as depicted in FIG. 4) extending from bottom surfaces of the shallow trenches 108 toward the backside surface 102B of the substrate 102 may be formed. The deep trench isolation regions 114 may be formed in the deep trenches 110, and the shallow trench isolation regions 118 may be formed in the shallow trenches 108.

The shallow trench isolation regions 118 may include silicon oxide, and the deep trench isolation regions 114 may include impurity doped polysilicon. For example, the deep trench isolation regions 114 may be formed of polysilicon doped with a p-type impurity such as boron (B). The impurities in the deep trench isolation regions 114 may function as gettering sites (or regions) to collect metal contaminants in the substrate 102. As a result, the metal contamination in the substrate 102 may be significantly reduced, and the dark current due to the metal contaminants may thus be significantly reduced.

Further, the deep trench isolation regions 114 may extend from the shallow trench isolation regions 118 toward the backside surface 102B of the substrate 102. Particularly, the deep trench isolation regions 114 may extend to the backside surface 102B of the substrate 102 as shown in FIG. 1. In these embodiments, the pixel regions 140 may be sufficiently electrically isolated from each other by the deep trench isolation regions 114, thereby reducing the crosstalk between the pixel regions 140.

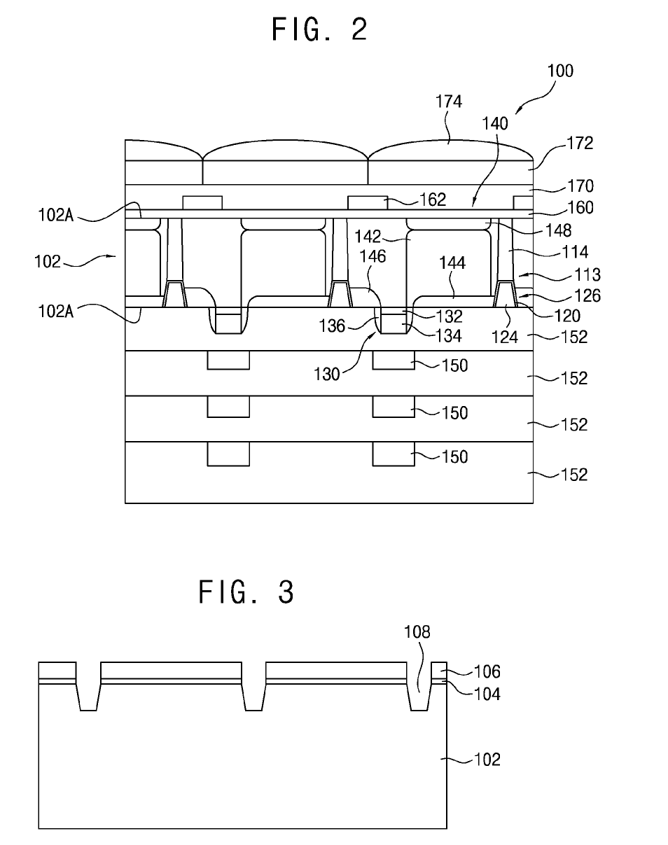

FIG. 2 is a cross-sectional view illustrating another example of the isolation regions 113 as shown in FIG. 1.

As can be seen in FIG. 2, shallow trenches 108 (as depicted in FIG. 3) may be formed in frontside surface portions of the substrate 102. Deep trenches 110 (as depicted in FIG. 4) extending from bottom surfaces of the shallow trenches 108 toward the backside surface 102B of the substrate 102 may also be formed. The deep trench isolation regions 114 may be formed in the deep trenches 110, and the shallow trench isolation regions 126 may be formed in the shallow trenches 108. Each of the shallow trench isolation regions 126 may include a liner insulating layer 120 and a silicon oxide region 124 formed on the liner insulating layer 120.

The liner insulating layers 120 may be formed on the deep trench isolation regions 114 and inner side surfaces of the shallow trenches 108, and the silicon oxide regions 124 may be formed by filling the shallow trenches 108 with silicon oxide. Each of the liner insulating layers 120 may include a silicon nitride layer formed by a low pressure chemical vapor deposition (LPCVD) process and/or a silicon oxide layer formed by a thermal oxidation process.

FIGS. 3 to 17 are cross-sectional views illustrating a method of manufacturing the backside illuminated image sensor 100 as shown in FIG. 1.

Referring to FIGS. 3 and 4, shallow trenches 108 and deep trenches 110 may be formed in a substrate 102. For example, the shallow trenches 108 and the deep trenches 110 may be formed by a reactive ion etching (RIE) process using a hard mask 106. Particularly, a pad oxide layer 104 may be formed on a frontside surface 102A of the substrate 102 by a thermal oxidation process, and the hard mask 106 may then be formed on the pad oxide layer 104. The hard mask 106 may include silicon nitride (Si₃N₄), borosilicate glass (BSG), boro-phospho-silicate glass (BPSG), or plasma enhanced tetraethyl orthosilicate (PETEOS).

After forming the hard mask 106, the shallow trenches 108 may be formed by a first RIE process using the hard mask 106. The first RIE process may be performed by using a reactive gas such as chlorine (Cl₂), fluorine (F) and bromine (Br).

Though not shown in the figures, a by-product layer (not shown) may be formed on inner surfaces of the shallow trenches 108 while performing the first RIE process. The by-product layer may be removed by a wet etching process using an etchant including hydrofluoric acid (HF), and a buffer oxide layer (not shown) may be formed on the inner surfaces of the shallow trenches 108 by a thermal oxidation process.

Then, the deep trenches 110 may be formed by a second RIE process as shown in FIG. 4. Though not shown in figures, a by-product layer (not shown) may be formed on inner surfaces of the shallow trenches 108 and the deep trenches 110 while performing the second RIE process. The by-product layer and the buffer oxide layer may be removed by a wet etching process after forming the deep trenches 110.

Referring to FIG. 5, an impurity doped polysilicon layer 112 may be formed on the frontside surface 102A of the substrate 102 so that the shallow trenches 108 and the deep trenches 110 are buried. For example, the impurity doped polysilicon layer 112 may be formed by a LPCVD process using a source gas including silicon (Si) and Boron (B). Further, a heat treatment process may be performed to activate impurities in the impurity doped polysilicon layer 112.

Alternatively, a polysilicon layer (not shown) may be formed on the frontside surface 102A of the substrate 102 so that the shallow trenches 108 and the deep trenches 110 are buried, and an ion implantation process may be performed to dope portions of the polysilicon layer in the deep trenches 110 with an impurity. For example, an ion implantation mask having openings corresponding to the deep trenches 110 may be formed on the polysilicon layer, and an ion implantation process using p-type impurities, such as boron (B), BF₂, and the like, may then be performed. The ion implantation mask may be a photoresist pattern formed by a photolithography process and may be removed by an ashing or strip process after performing the ion implantation process.

Referring to FIG. 6, the impurity doped polysilicon layer 112 may be partially removed by an isotropic etching process, thereby forming deep trench isolation regions 114 in the deep trenches 110. The deep trench isolation regions 114 made of impurity doped polysilicon, as described above, may function as gettering regions for collecting metal contaminants in the substrate 102.

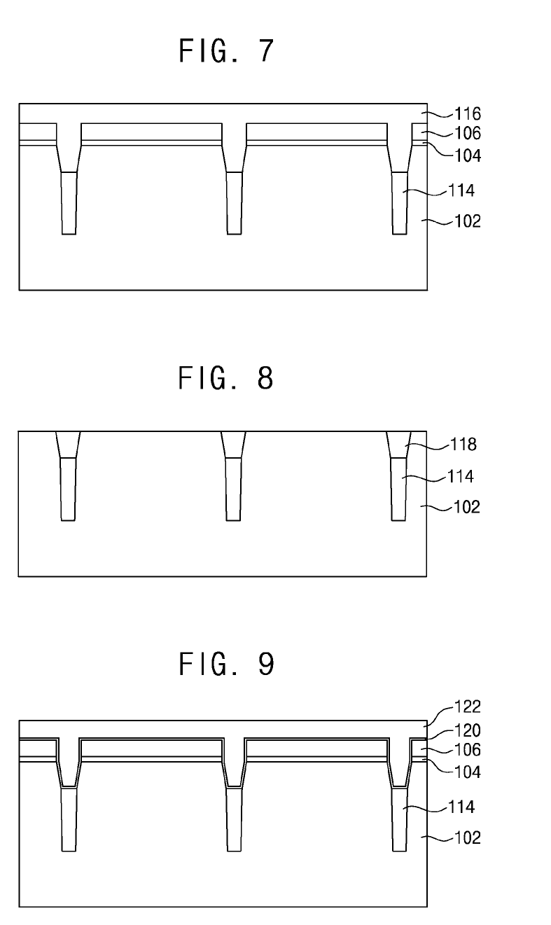

Referring to FIG. 7, an insulating layer 116 may be formed on the frontside surface 102A of the substrate 102 so that the shallow trenches 108 are buried. For example, a silicon oxide layer 116 may be formed on the substrate 102 by a high density plasma chemical vapor deposition process so that the shallow trenches 108 are buried.

Referring to FIG. 8, the silicon oxide layer 116 may be partially removed by a chemical mechanical polish (CMP) process, thereby forming shallow trench isolation regions 118 in the shallow trenches 108. At this time, the pad oxide layer 104 and the hard mask 106 may be removed by the CMP process.

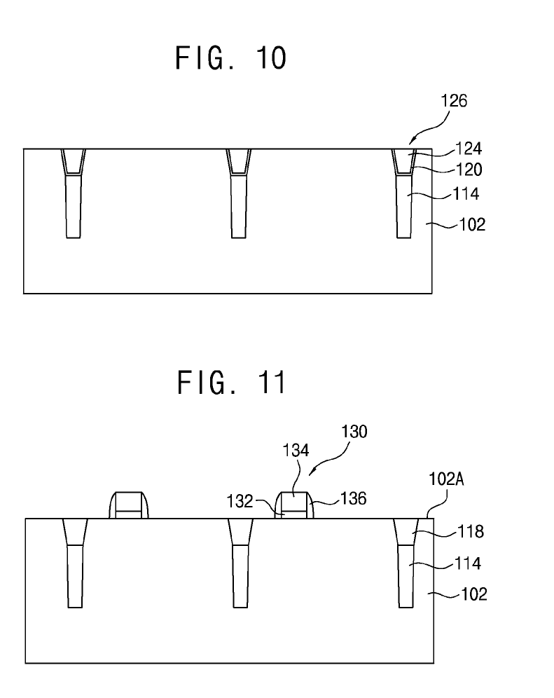

Alternatively, after forming the deep trench isolation regions 114, a liner insulating layer 120 may be formed on the deep trench isolation regions 114 and inner side surfaces of the shallow trenches 108 as shown in FIG. 9. Then, a silicon oxide layer 122 may be formed on the liner insulating layer 120 so that the shallow trenches 108 are buried. For example, the liner insulating layer 120 may include silicon nitride and/or silicon oxide.

Further, a CMP process may be performed so that the frontside surface 102A of the substrate 102 is exposed, thereby forming shallow trench isolation regions 126 including the liner insulating layer 120 and silicon oxide regions 124 in the shallow trenches 108 as shown in FIG. 10.

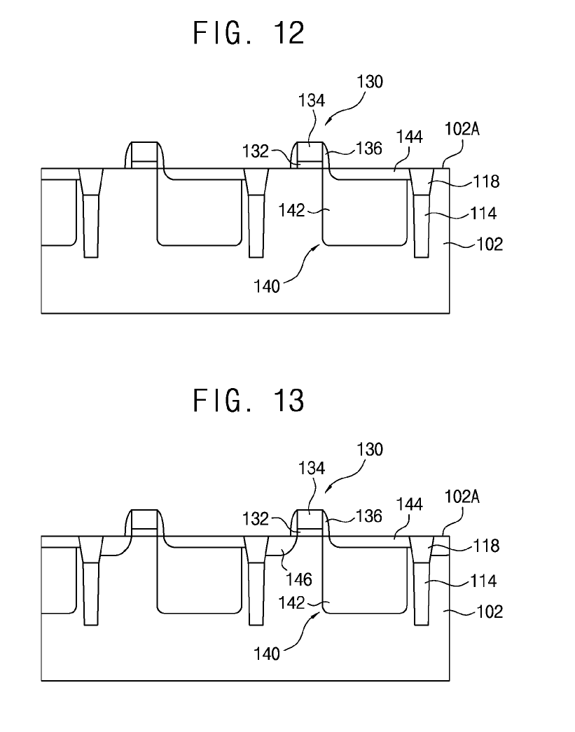

Referring to FIG. 11, transfer gate structures 130 may be formed on active regions defined by the shallow trench isolation regions 118. Each of the transfer gate structures 130 may include a gate insulating layer 132, a gate electrode 134 formed on the gate insulating layer 132 and gate spacers 136 formed on side surfaces of the gate electrode 134. Further, though not shown in figures, reset gate structures, source follower gate structures and select gate structures may be simultaneously formed with the transfer gate structures 130 on the frontside surface 102A of the substrate 102.

Referring to FIG. 12, charge accumulation regions 142 used as pixel regions 140 may be formed in the substrate 102. The substrate 102 may have a first conductivity type, and charge accumulation regions 142 having a second conductivity type may be formed in the active regions of the substrate 102. For example, n-type charge accumulation regions 142 may be formed in a p-type substrate 102. Particularly, the n-type charge accumulation regions 142 may be n-type impurity diffusion regions and may be formed by an ion implantation process.

Further, frontside pinning layers 144 having the first conductivity type may be formed between the frontside surface 102A of the substrate 102 and the charge accumulation regions 142. For example, p-type frontside pinning layers 144 may be formed between the frontside surface 102A of the substrate 102 and the n-type charge accumulation regions 142 by an ion implantation process. The p-type frontside pinning layers 144 may be p-type impurity diffusion regions. The n-type charge accumulation regions 142 and the p-type frontside pinning layers 144 may be activated by a subsequent rapid heat treatment process.

Referring to FIG. 13, floating diffusion regions 146 having the second conductivity type may be formed in frontside surface portions of the substrate 102 to be spaced apart from the charge accumulation regions 142. For example, the floating diffusion regions 146 may be n-type high concentration impurity regions, which may be formed by an ion implantation process. At this time, the transfer gate structures 130 may be arranged on channel regions between the charge accumulation regions 142 and the floating diffusion regions 146.

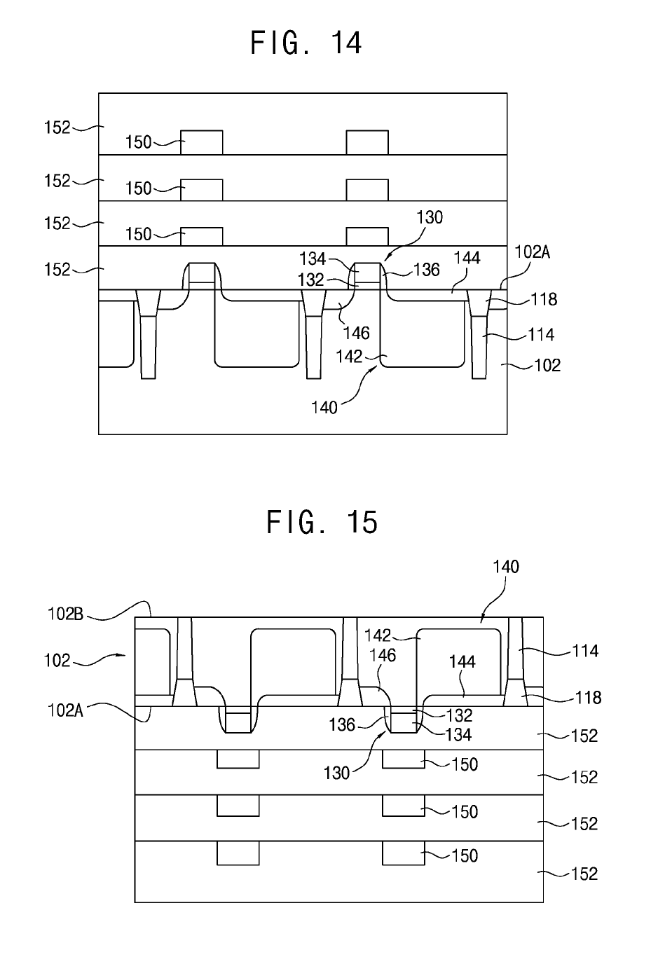

Referring to FIG. 14, wiring layers 150 may be formed on the frontside surface 102A of the substrate 102 to be electrically connected with the pixel regions 140. Further, insulating layers 152 may be formed on the frontside surface 102A of the substrate 102 and between the wiring layers 150.

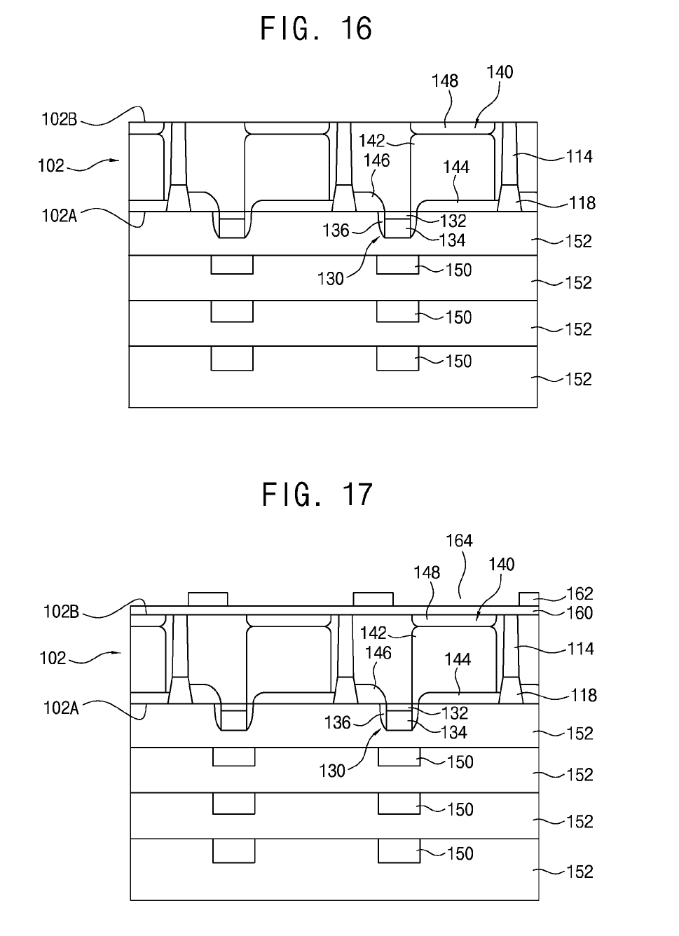

Referring to FIG. 15, a back-grinding process or a CMP process may be performed in order to reduce a thickness of the substrate 102. For example, the back-grinding process or the CMP process may be performed so that the deep trench isolation regions 114 are exposed.

Referring to FIG. 16, backside pinning layers 148 having the first conductivity type may be formed between a backside surface 102B of the substrate 102 and the charge accumulation regions 142. For example, p-type impurity regions functioning as the backside pinning layers 148 may be formed by an ion implantation process, and may then be activated by a subsequent laser annealing process.

Alternatively, the backside pinning layers 148 may be formed prior to the charge accumulation regions 142. For example, after forming backside pinning layers 148 using an ion implantation process, the charge accumulation regions 142 may be formed on the backside pinning layers 148, and the frontside pinning layers 144 may then be formed on the charge accumulation regions 142. In such case, the backside pinning layers 148 may be activated by the rapid heat treatment process along with the charge accumulation regions 142 and the frontside pinning layers 144. In such case, the back-grinding process may be performed such that the deep trench isolation regions 114 and the backside pinning layers 148 are exposed.

Referring to FIG. 17, an anti-reflective layer 160 may be formed on the backside surface 102B of the substrate 102, and a light-blocking pattern 162 may then be formed on the anti-reflective layer 160. For example, the anti-reflective layer 160 may be formed of silicon nitride, and the light-blocking pattern 162 may be formed of a metal such as tungsten. Particularly, the light-blocking pattern 162 may have openings 164 corresponding to the pixel regions 140 and may be used to improve the crosstalk of the backside illuminated image sensor 100.

Then, a passivation layer 170 may be formed on the anti-reflective layer 160 and the light-blocking pattern 162 as shown in FIG. 1. For example, the passivation layer 170 may include silicon oxide, silicon nitride or silicon oxynitride, and may be formed by a chemical vapor deposition process. Further, a color filter layer 172 and a micro lens array 174 may be sequentially formed on the passivation layer 170.

In accordance with the embodiments of the present disclosure as described above, a backside illuminated image sensor 100 may include pixel regions 140 disposed in a substrate 102, wiring layers 150 disposed on a frontside surface 102A of the substrate 102 and electrically connected with the pixel regions 140, a color filter layer 172 disposed on a backside surface 102B of the substrate 102, a micro lens array 174 disposed on the color filter layer 172, and isolation regions 113 configured to electrically isolate the pixel regions 140 from each other. Particularly, each of the isolation regions 113 may include a deep trench isolation region 114 and a shallow trench isolation region 118 disposed on the deep trench isolation region 114.

The deep trench isolation regions 114 may be formed of impurity doped polysilicon and may function as gettering regions for collecting metal contaminants in the substrate 102. Thus, the dark current due to the metal contaminants may be significantly reduced.

Further, the deep trench isolation regions 114 may extend from the shallow trench isolation regions 118 to the backside surface 102B of the substrate 102, and the pixel regions 140 may thus be sufficiently electrically isolated from each other by the deep trench isolation regions 114. As a result, the crosstalk between the pixel regions 140 may be significantly reduced.

Although the backside illuminated image sensor 100 and the method of manufacturing the same have been described with reference to specific embodiments, they are not limited thereto. Therefore, it will be readily understood by those skilled in the art that various modifications and changes can be made thereto without departing from the spirit and scope of the present disclosure defined by the appended claims.

1. A backside illuminated image sensor comprising:
a substrate presenting a frontside surface and a backside surface;
a plurality of pixel regions disposed in the substrate;
a plurality of wiring layers disposed on the frontside surface of the substrate and electrically connected with the plurality of pixel regions;
a color filter layer disposed on the backside surface of the substrate;
a micro lens array disposed on the color filter layer; and
a plurality of isolation regions configured to electrically isolate the pixel regions from each other;
wherein each of the plurality of isolation regions comprises a deep trench isolation region and a shallow trench isolation region disposed on the deep trench isolation region.

2. The backside illuminated image sensor of claim 1, wherein each deep trench isolation region comprises impurity doped polysilicon.

3. The backside illuminated image sensor of claim 1, wherein each shallow trench isolation region comprises silicon oxide.

4. The backside illuminated image sensor of claim 1, wherein each shallow trench isolation region comprises a liner insulating layer and a silicon oxide region disposed on the liner insulating layer.

5. The backside illuminated image sensor of claim 1, wherein each deep trench isolation region extends from the corresponding shallow trench isolation region to the backside surface of the substrate.

6. The backside illuminated image sensor of claim 1, wherein each of the plurality of pixel regions comprises:
a charge accumulation region disposed in the substrate; and
a frontside pinning layer disposed between the frontside surface of the substrate and the charge accumulation region.

7. The backside illuminated image sensor of claim 6, wherein the each of the plurality of pixel regions further comprises a backside pinning layer disposed between the backside surface of the substrate and the charge accumulation region.

8. The backside illuminated image sensor of claim 1, further comprising:
an anti-reflective layer disposed on the backside surface of the substrate;
a light-blocking pattern disposed on the anti-reflective layer and defining a plurality of openings, each opening corresponding to one of the plurality of pixel regions; and
a passivation layer disposed on the anti-reflective layer and the light-blocking pattern,
wherein the color filter layer is disposed on the passivation layer.

9. A backside illuminated image sensor comprising:
a plurality of pixel regions disposed in a substrate;
plurality of wiring layers disposed on a frontside surface of the substrate and electrically connected to the plurality of pixel regions;
a color filter layer disposed on a backside surface of the substrate;
a micro lens array disposed on the color filter layer;
plurality of isolation regions configured to electrically isolate the plurality of pixel regions from each other; and
a plurality of gettering regions extending from the isolation regions toward the backside surface of the substrate to collect contaminants in the substrate.

10. The backside illuminated image sensor of claim 9, wherein the plurality of gettering regions comprise impurity doped polysilicon.

11. The backside illuminated image sensor of claim 9, wherein the plurality of isolation regions are disposed in frontside surface portions of the substrate, and the plurality of gettering regions extend to the backside surface of the substrate.

12. A method of manufacturing a backside illuminated image sensor, the method comprising:
forming a plurality of isolation regions in a substrate configured to electrically isolate a plurality of pixel regions from each other;
forming the plurality of pixel regions in the substrate;
forming a plurality of wiring layers on a frontside surface of the substrate to be electrically connected to the plurality of pixel regions;
forming a color filter layer on a backside surface of the substrate; and
forming a micro lens array on the color filter layer;
wherein forming the plurality of isolation regions comprises:
forming a plurality of deep trench isolation regions in the substrate; and
forming a plurality of shallow trench isolation regions on the plurality of deep trench isolation regions.

13. The method of claim 12, wherein the plurality of deep trench isolation regions comprise impurity doped polysilicon.

14. The method of claim 12, wherein forming the plurality of isolation regions further comprises:
forming shallow trenches in frontside surface portions of the substrate; and
forming deep trenches extending from the shallow trenches toward the backside surface of the substrate;
wherein the plurality of deep trench isolation regions are formed in the plurality of deep trenches, and the plurality of shallow trench isolation regions are formed in the plurality of shallow trenches.

15. The method of claim 14, wherein forming the plurality of isolation regions further comprises forming a liner insulating layer on inner surfaces of the plurality of shallow trenches.

16. The method of claim 14, wherein forming the plurality of deep trench isolation regions comprises:
forming an impurity doped polysilicon layer on the frontside surface of the substrate so that the plurality of deep trenches are buried; and
partially removing the impurity doped polysilicon layer in order to form the plurality of deep trench isolation regions in the plurality of deep trenches.

17. The method of claim 14, wherein forming the plurality of deep trench isolation regions comprises:
forming a polysilicon layer on the frontside surface of the substrate so that the plurality of deep trenches are buried;
performing an ion implantation process for doping portions of the polysilicon layer with an impurity; and
partially removing the polysilicon layer in order to form the plurality of deep trench isolation regions in the plurality of deep trenches.

18. The method of claim 12, further comprising:
performing a back-grinding process such that the plurality of deep trench isolation regions are exposed after forming the plurality of wiring layers.

19. The method of claim 12, wherein forming the plurality of pixel regions comprises:
forming a plurality of charge accumulation regions in the substrate; and
forming a plurality of frontside pinning layers between the frontside surface of the substrate and the plurality of charge accumulation regions.

20. The method of claim 19, wherein forming the plurality of pixel regions further comprises:
forming backside pinning layers between the backside surface of the substrate and the charge accumulation regions.

21. The method of claim 12, further comprising:
forming an anti-reflective layer on the backside surface of the substrate;
forming a light-blocking pattern defining a plurality of openings, each opening corresponding to a pixel region of the plurality of pixel regions on the anti-reflective layer; and
forming a passivation layer on the anti-reflective layer and the light-blocking pattern,
wherein the color filter layer is formed on the passivation layer.
